(19) United States
(12) Patent Application Publication
(10) Pub. No.: US 2009/0224407 A1
(43) Pub. Date: Sep. 10, 2009

(54) SEMICONDUCTOR DEVICE

(75) Inventor: Kango NAGAYOSHI, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/390,657

(22) Filed: Feb. 23, 2009

(30) Foreign Application Priority Data
Mar. 4, 2008 (JP) 2008-053601
Jan. 27, 2009 (JP) 2009-015531

(51) Int. Cl. H01L 23/48

(52) U.S. Cl. 257/773; 257/E23.01

(57) ABSTRACT

A semiconductor device includes a plurality of first and second pads aligned along a first direction. The lengths of the first pads in parallel with the first direction are longer than those of the second pads in parallel with the first direction.

### BACKGROUND OF THE INVENTION

1. Field of the Invention

The present invention relates to a semiconductor device including a circuit unit and multiple pads.

Priority is claimed on Japanese Patent Application Nos. 2008-53601 and 2009-15531, filed Mar. 4, 2008 and Jan. 27, 2009, respectively, the contents of which are incorporated herein by reference.

2. Description of the Related Art

Generally, semiconductor devices include multiple pads for data or signals to be input and/or output. Usually, the same pad is targeted for both a wafer probe test and wire-bonding for packaging in a conventional semiconductor device including a circuit unit and multiple pads. Thereby, a scratch by a probe causes debonding and therefore a reduction in yield. Therefore, it is necessary to see to it that probing does not affect wire bonding.

Additionally, the number of pads has to be increased as the number of inputs and outputs of data is increased. Although the chip size is becoming smaller with progress in processing technologies, the number of pads required for input and output of data is becoming greater, causing a problem in that the pads cannot be included in a chip if aligned in a line. For this reason, the areas of the pads have to be smaller.

As a first conventional case, a semiconductor device disclosed in Japanese Patent, Laid-open Publication No. H11-74464 includes pads P3 and P4 as shown in FIG. 8. The pads P4 are larger than the pads P3. Each of the pads P3 and P4 includes a wire-bonding region 14, a probe region 15, and a connection portion connecting the wire-bonding region 14 and the probe region 15. The connection portion 16 of the pad P3 is shorter than the connection portion 17 of the pad P4. The pads P3 and P4 have the same width in the direction along which the pads P3 and P4 are aligned (hereinafter, “alignment direction”), and different widths in the direction perpendicular to the alignment direction. The wire-bonding region 14 and the probe region 15 included in each pad are connected in the direction perpendicular to the alignment direction. The pads P3 and P4 are alternately aligned with the sides thereof on the side of a circuit unit being lined up, thereby enabling probing at a narrow pitch. Since the wire-bonding region 14 is distanced from the probe region 15, a scratch by a probe does not affect packaging.

As a second conventional case, a semiconductor device disclosed in Japanese Patent, Laid-open Publication No. 2006-222147 includes pads P5 and substantially-rectangular marks P6 as shown in FIG. 9. The marks P6 are smaller than the pads P5. Each of the pads P5 includes a wire-bonding region 24 and a probe region 25 connected to each other in the direction perpendicular to the alignment direction, thereby preventing a scratch by a probe from affecting packaging. The mark P6 is used for identifying a boundary between the wire-bonding region 24 and the probe region 25.

As a third conventional case, a semiconductor device disclosed in Japanese Patent, Laid-open Publication No. 2003-332450 includes a control circuit 6, a pad P7 connected to the control circuit 6, and pads P8 and P9, as shown in FIGS. 10 and 11. The pads P8 are targeted for a probe test for multiple I/O (two I/O in the illustrated case). The pads P9 are smaller than pads P8. The switch control circuit 6 controls which of the pads P8 and P9 are to be connected to internal circuits. Each of the pads P8 and P9 is longer in the direction perpendicular to the alignment direction.

As a fourth conventional case, a conventional semiconductor device disclosed in Japanese Patent, Laid-open Publication No. 2007-96216 includes ESD protect elements P11, I/O circuits P12, pads P13 targeted for a probe test, and pads P14 targeted for wire-bonding, as shown in FIG. 12. The pads P13 and P14 have the same function, but are independent from one another so that a scratch by a probe does not affect packaging.

As disclosed in “Shizuo Ito, VLSI memory, p. 183-185, 1994, Baihukan”, methods of reducing a probe test time have conventionally been used. Generally in current wafer probe tests, the number of chips to be simultaneously measured is increased to achieve an I/O reduction leading to a reduction in test costs.

Currently, various test methods using a reduction test have been established. There is no need to probe every pad in wafer probe tests.

In the first conventional case, however, the pads P3 and P4 occupy the large area since the wire-bonding region 14 and the prove region 15 which are included in every pad are connected in the direction perpendicular to the alignment direction, thereby greatly decreasing the area of the circuit unit. If the sides of the pads P3 and P4 on the side of the circuit unit are not aligned, the processing of the circuit unit will be complicated. For this reason, the sides of the pads P3 and P4 on the side of the circuit unit are aligned to the side of a pad positioned most inside. As a result, large areas around the pads are wastefully used.

In the second conventional case, the mark P6 is used for neither a probe test nor wire-bonding, thereby decreasing the area for pads to be provided. Additionally, the pads occupy the large area similarly to the first conventional case, thereby greatly decreasing the area of the circuit unit.

Common to the first and second conventional cases, each of the pads P3 to P5 includes the wire-bonding region 14 and the probe region 15 and is substantially rectangular if planarly viewed. If the pads are aligned with the longer sides thereof being along the alignment direction, the number of pads that can be aligned per unit length decreases, and therefore all of the pads cannot be aligned in a line. In order to align all of the pads in a line, the pads have to be aligned with the shorter sides thereof being along the alignment direction. As a result, the pads occupy the larger areas, thereby further decreasing the area of the circuit unit.

In the third conventional case, the pads not to be probed are made smaller than the pads to be probed, thereby reducing the pitch of the pads and saving space in the alignment direction. However, the pads occupy large areas in the direction perpendicular to the alignment direction, thereby decreasing the area of the circuit unit similarly to the first and second conventional cases. Further, there is no teaching about wire-bonding though probing is disclosed.

In the fourth conventional case, pads for different purposes, such as a wafer test or wire-bonding, are separately provided. Thereby, space among the pads is a waste.

In summary, a scratch by a probe causes debonding of pads and a reduction in yield if the probe and wire-bonding regions adjacent to each other or overlapping each other are included in one pad.

Further, the number of pads to be wire-bonded does not decrease even if the chip size decreases with a decrease in the process rule, and the number of pads have to be increased for a product having many I/O. If every pad is made in a same size, all pads cannot be aligned in a line along sides of a chip. If all pads are aligned in multiple lines, the area of pads greatly increases. If pads are made smaller in size to be aligned in a line, the probe region and the wire-bonding region further overlap each other, causing debonding of pads.

### SUMMARY

In one embodiment, there is provided a semiconductor device that may include a plurality of first and second pads aligned along a first direction. The lengths of the first pads in parallel with the first direction are longer than those of the second pads in parallel with the first direction.

In another embodiment, there is provided a semiconductor device that may include first and second pads, first and second buffers, and a comparison circuit. The first pad is larger than the second pad. The first buffer outputs first data to the first pad. The second buffer outputs second data to the second pad. The comparison circuit compares the first data with the second data and outputs a result of the comparison to the first pad.

Accordingly, the areas of the pads can be smaller than those of conventional pads, particularly in a second direction perpendicular to the first direction. Thereby, the first and second pads can be aligned in a line, and the larger area can be saved for a circuit unit compared with conventional cases.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plane view illustrating pads of a semiconductor device according to a first embodiment of the present invention;

FIG. 1B is a partially enlarged view of the pads shown in FIG. 1A;

FIG. 2 illustrates a process flow of a probe test and wire-bonding sequentially performed on a conventional semiconductor device;

FIG. 3 illustrates a process flow of a probe test and wire-bonding sequentially performed on the semiconductor device according to the first embodiment;

FIGS. 4A and 4B illustrate an I/O unit of a conventional semiconductor device;

FIG. 5 illustrates an I/O unit of the semiconductor device according to the first embodiment;

FIG. 6 illustrates an I/O unit of a conventional semiconductor circuit;

FIG. 7 illustrates the I/O unit of the semiconductor device according to the first embodiment;

FIG. 8 is a plane view illustrating pads of a semiconductor device in a first conventional case;

FIG. 9 is a plane view illustrating pads of a semiconductor device in a second conventional case;

FIG. 10 is a plane view illustrating pads and an internal circuit of a semiconductor device in a third conventional case;

FIG. 11 is a plane view illustrating the pads shown in FIG. 10; and

FIG. 12 is a plane view illustrating pads of a semiconductor device in a fourth conventional case.

### DETAILED DESCRIPTION OF THE PREFERRED EMBODIMENTS

The invention will now be described herein with reference to illustrative embodiments. The accompanying drawings explain a semiconductor device and a method of manufacturing the semiconductor device in the embodiments, and the size, the thickness, and the like of each illustrated portion might be different from those of each portion of an actual semiconductor device.

Those skilled in the art will recognize that many alternative embodiments can be accomplished using the teachings of the present invention and that the invention is not limited to the embodiments illustrated herein for explanatory purposes.

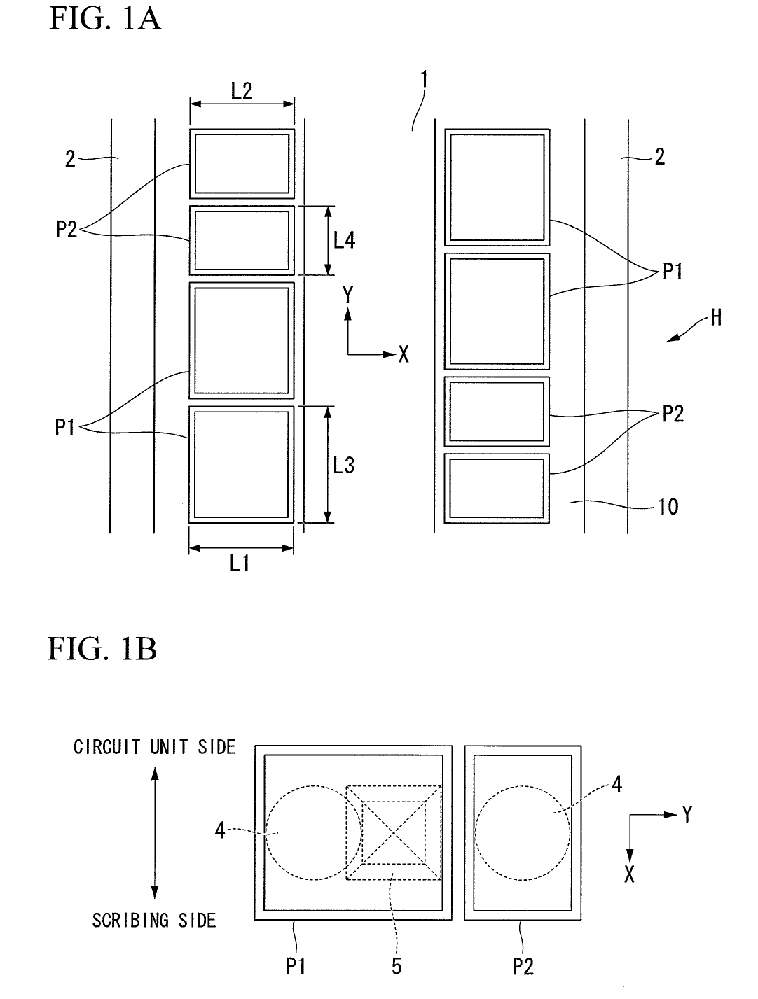

As shown in FIG. 1A, a semiconductor device H according to a first embodiment of the present invention mainly includes a semiconductor substrate 10, a circuit unit 1 provided on the semiconductor substrate 10, and multiple first and second pads P1 and P2 aligned in a line on both sides of the circuit unit 1. The pads P1 and P2 are connected to the circuit unit 1 through wiring. The circuit unit 1 includes, for example, a memory circuit and a CPU (central processing unit), i.e., a circuit element for implementing functions of the semiconductor device H.

An X-axis direction is perpendicular to a direction in which the pads are aligned (hereinafter, “alignment direction”), and a Y-axis direction is perpendicular to the X-axis direction and in parallel with the alignment direction and sides of the semiconductor device H.

As shown in FIG. 1B, the first pad P1 includes a wire-bonding region 4 and a probe region 5. The second pad P2 includes only the wire-bonding region 4. The first and second pads P1 and P2 are aligned in a line along the Y-axis direction. A scribe region 2 is provided outside the line of the first and second pads P1 and P2. The wire-bonding region 4 is a region to which a bonding wire is connected. The probe region 5 is a region that a probe of a probe card contacts in a probe test.

The pads P1 and P2 are rectangular when planarly viewed. The first pad P1 is larger than the second pad P2. The first and second pads P1 and P2 have the same width along the X-axis direction. In other words, a length L1 of the first pad P1 along the X-axis direction is substantially equal to a length L2 of the second pad P2 along the X-axis direction. On the other hand, a length L3 of the first pad P1 along the Y-axis direction is longer than a length L4 of the second pad P2 along the Y-axis direction. The first pads P1 are substantially rectangular when planarly viewed and aligned with the longer sides thereof being along the Y-axis direction. The second pads P2 may be rectangular or square when planarly viewed.

The ratio of the number of the first and second pads P1 and P2 may appropriately be selected based on, for example, an I/O reduction-test mode, and not be particularly limited. For example, approximately P1:P2=1:3 is preferable for all pads, and P1:P2=1:7-1:15 is preferable only for I/O pads.

The wire-bonding region 4 and the probe region 5 that are included in the first pad P1 are aligned in the Y-axis direction. The areas of the wire-bonding region 4 and the probe region 5 are respectively determined based on the areas required for probing and wire-bonding, and the area of the first pad P1 is determined based on the areas of the wire-bonding region 4 and the probe region 5. The probe region 5 may partially overlap the wire-bonding region 4 to the extent that the reliability based on the precision of probing does not degrade, thereby substantially reducing the area of the first pad P1. Generally, 20 to 30% of the area of the probe region 5 are allowed to overlap the wire-bonding region 4. The area of the second pad P2 is determined based on the area required for wire-bonding.

A pad interval is determined to be equal to or more than the minimum of a probe interval of a probe card in consideration of the areas of the pads. A probe test is carried out in an I/O reduction-test mode with a probe being in contact with the probe region 5 of the first pad P1. In the I/O reduction-test mode, both a test of the circuit unit 1 with respect to the first pad P1 and a test of the circuit unit 1 with respect to the second pad P2 can simultaneously be carried out with the probe being in contact with the first pad P1.

Since the first and second pads P1 and P2 are aligned in this manner, i.e., the first pad P1 to be probed includes the wire-bonding region 4 and the probe region 5, and the second pad P2 not to be probed includes only the wire-bonding region 4, the areas of the pads to be provided can be reduced compared with those of conventional pads.

Depending on an I/O reduction-test mode, the number of the second pads P2 not to be probed is greater than that of the first pads P1 to be probed. Thereby, the entire area targeted for probing is smaller than that in conventional cases. Therefore, the first pads P1 to be probed can be aligned in a line with the longer sides thereof being along the Y-axis direction (alignment direction).

By the pads being aligned in this manner, the shorter sides of the first and second pads P1 and P2 are in parallel with the X-axis direction. In other words, the widths of the first and second pads P1 and P2 along the X-axis direction are smaller than those in conventional cases. Thereby, the area for the circuit unit 1 can maximally be saved. Further, the first and second pads P1 and P2 are aligned in a line, simplifying a probe test and packaging compared with conventional cases.

Additionally, the first pad P1 to be probed includes the wire-bonding region 4 and the probe region 5 separately, and the second pad P2 not to be probed includes only the wire-bonding region 5. Thereby, only the probe region 5 is probed in a wafer probe test, preventing debonding upon packaging and therefore improving the yield of packaging.

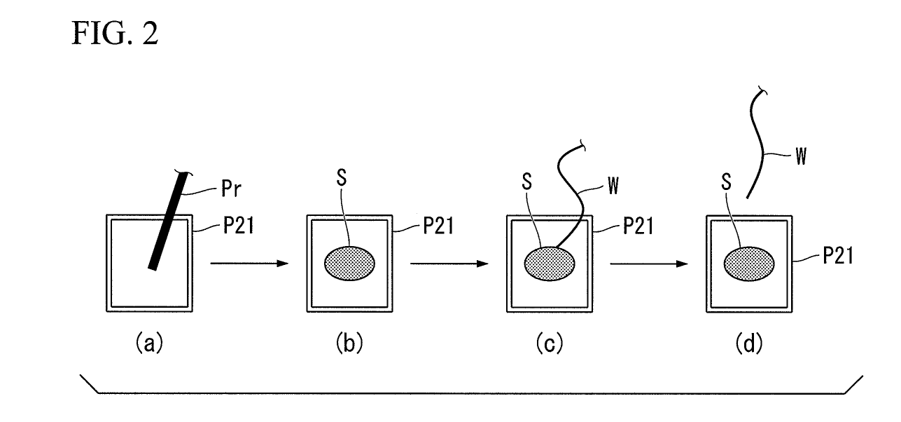

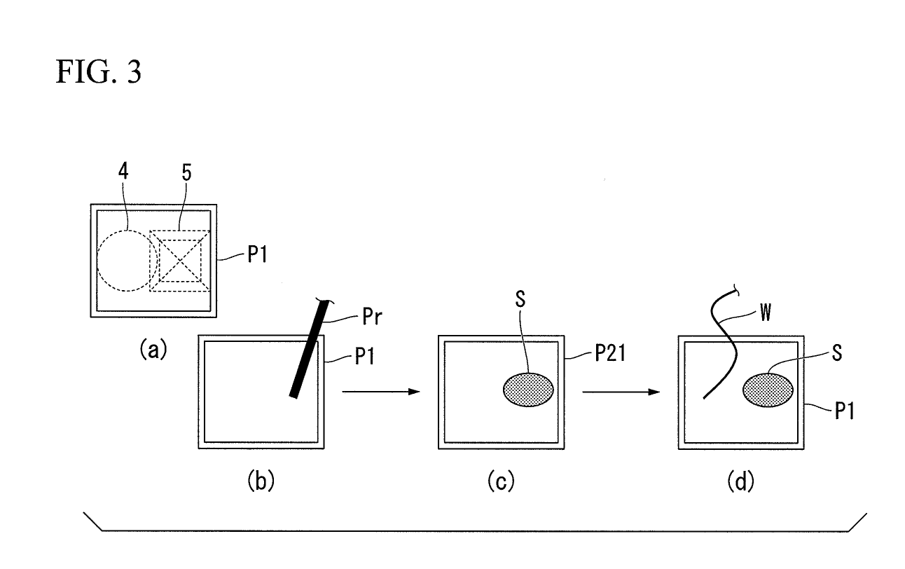

FIG. 2 illustrates a process flow of a probe test and wire-bonding sequentially performed on a conventional pad P21. FIG. 3 illustrates a process flow of a probe test and wire-bonding sequentially performed on the pad P1 according to the first embodiment.

The probe region for a probe test and a wire-bonding region for wire-bonding upon packaging are the same in the pad 21 shown in FIG. 2. If a probe Pr contacts the pad P21 in a probe test as shown in FIG. 2(a), a scratch S occurs in the wire-bonding region of the pad P21 as shown in FIG. 2(b). As a result, a wire W, even if wire-bonded to the pad P21 as shown in FIG. 2(c), is debonded therefrom because of the scratch S formed in the wire-bonding region, as shown in FIG. 2(d).

On the other hand, the wire-bonding region 4 and the probe region 5 are separately provided in the pad P1 shown in FIG. 3(a). As a result, if a probe Pr contacts the probe region 5 of the pad P1 as shown in FIG. 3(b), a scratch S occurs only in the probe region 5 as shown in FIG. 3(c). Therefore, a wire W, if bonded to the wire-bonding region 4 of the pad P1, is not debonded therefrom upon wire-bonding since the scratch S is not formed in the wire-bonding region 4.

As explained above, according to the first embodiment, the yield of packaging which has been degraded due to debonding can be improved.

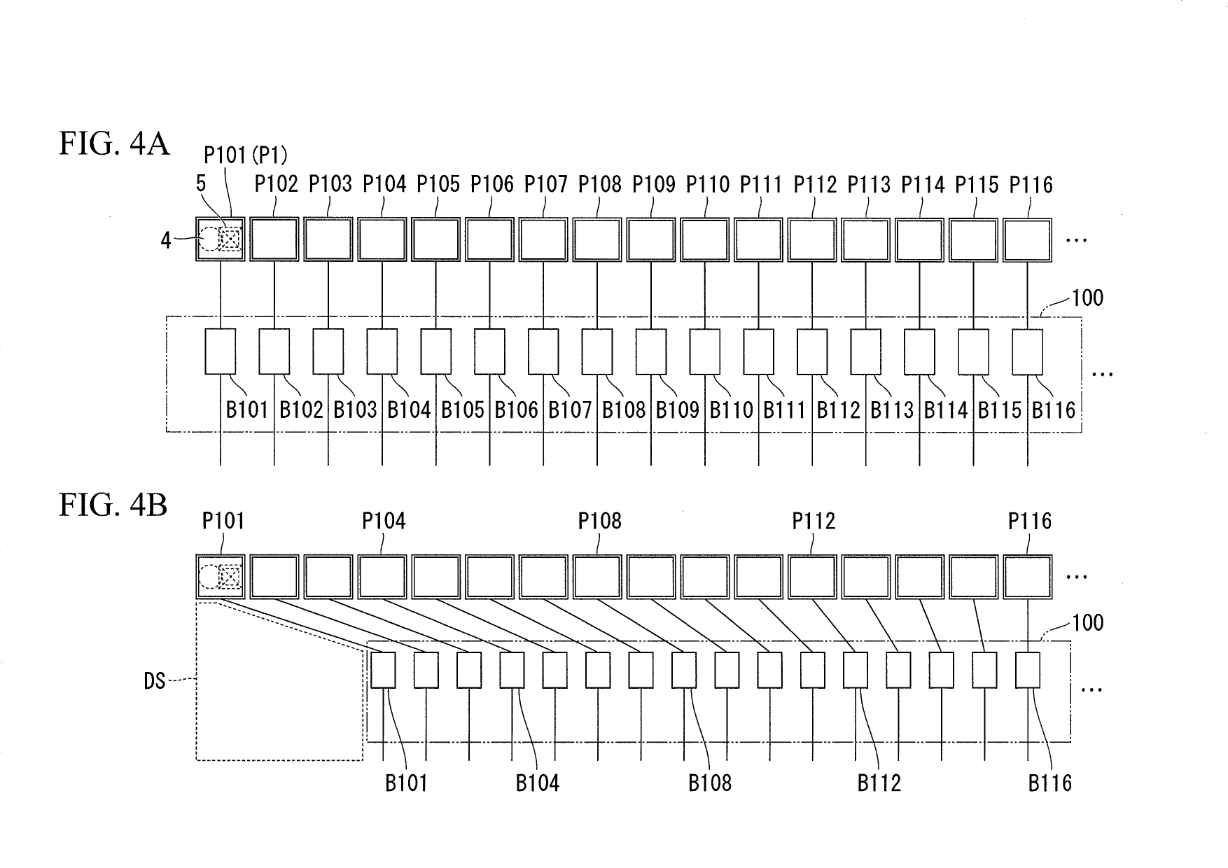

FIGS. 4A and 4B illustrate an I/O unit of a conventional semiconductor device.

The I/O unit of the conventional semiconductor device shown in FIG. 4A includes pads P101 to P116 and a circuit unit 100. Only I/O pads are shown, and power pads are not shown in FIGS. 4A and 4B. The pads P101 to P116 shown in FIG. 4 are first pads each including both the wire-bonding region 4 and the probe region 5.

The circuit unit 100 includes I/O buffers B101 to B116. If a read command is input to the conventional semiconductor device, the buffers B101 to B116 output data read from memory cells not shown in FIG. 4A to the pads P101 to P116, respectively. Upon wafer-probing, for example, a comparator of a semiconductor test apparatus determines the logical levels of signals output from the I/O buffers B101 to B116 through probes electrically connected to the pads P101 to P116, and thereby determines whether or not the semiconductor device is defective.

If the circuit unit 100 is reduced in size as shown in FIG. 4B, dead space DS occurs since the pads P101 to P116 cannot be changed in size. On the other hand, dead space does not occur in the semiconductor device H of the first embodiment as explained later, and therefore the pads P101 to P116 (first and second pads P1 and P2) can be aligned.

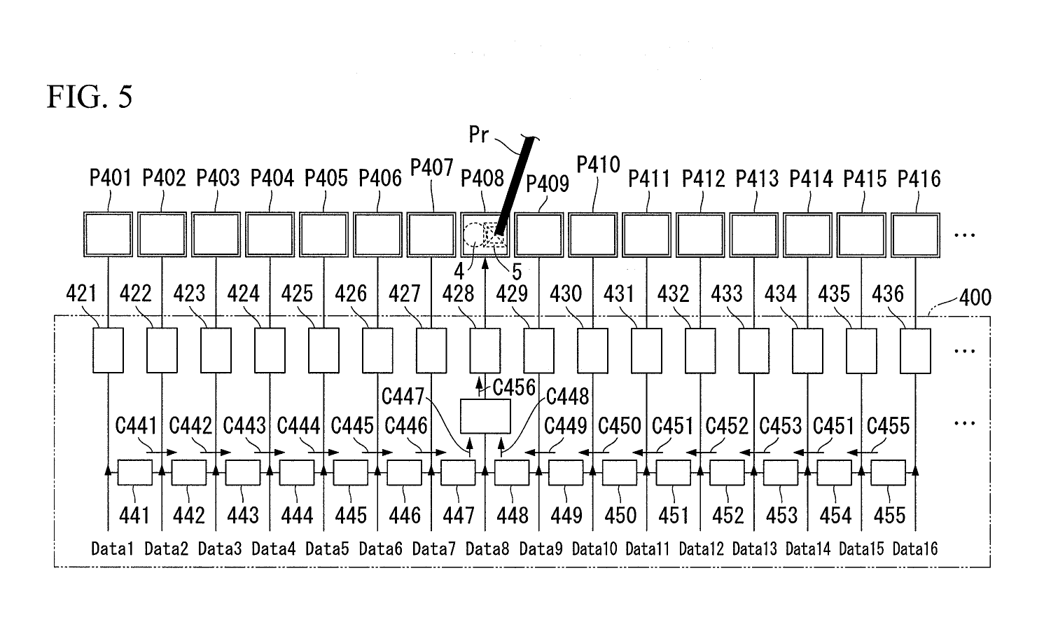

FIG. 5 illustrates an I/O unit of the semiconductor device H according to the first embodiment. An I/O reduction-test mode upon wafer-probing performed on the semiconductor device H is explained with reference to FIG. 5.

The I/O unit of the semiconductor device H shown in FIG. 5 includes pads P401 to P416 and a circuit unit 400. The pad P408 of the pads P401 to P416 is the first pad to be probed and includes the wire-bonding region 4 and the probe region 5. The rest of the pads are the second pads not to be probed and include only the wire-bonding region 4, though not shown. Only the I/O pads are shown, and power pads are not shown in FIGS. 5 to 7.

The circuit unit 400 includes 10 buffers 421 to 436 and comparison circuits 441 to 455. If a read command is input to the semiconductor device H in a normal mode, the I/O buffers 421 to 436 output Data 1 to Data 16 read from memory cells not shown in FIG. 5 to the pads P401 to P416, respectively.

In the I/O reduction-test mode, on the other hand, the I/O buffer 428 of the I/O buffers 421 to 436 outputs data obtained by the comparison circuits 441 to 455 reducing Data 1 to Data 16 to the pad P408 as a reduction result.

Upon wafer-probing, for example, a comparator of a semiconductor test apparatus determines the logical level of a signal output from the I/O buffer 428 through a probe electrically connected to the pad P408, and thereby determines whether or not the semiconductor device H is defective.

Hereinafter, operations of the comparison circuits 441 to 455 reducing Data 1 to Data 16 are explained. The comparison circuits 441 and 455 compares the logical levels of two input signals and outputs a comparison-result signal as a comparison result to the next comparison circuit 442 and 454, respectively. For example, the comparison circuit 441 compares the logical levels of Data 1 and Data 2 and outputs a comparison-result signal C441 to the comparison circuit 442.

Each of the other comparison circuits 442 to 454 performs a first comparison of the logical levels of two input data, followed by a second comparison of the logical levels of a comparison-result signal obtained from the first comparison and the comparison-result signal input from the anterior comparison circuit, and then outputs a comparison-result signal obtained from the second comparison to the posterior comparison circuit. For example, the comparison circuit 442 compares the logical levels of Data 2 and Data 3, compares the logical level of a comparison-result signal obtained from the comparison of Data 2 and Data 3 and the logical level of the comparison-result signal C441, and then outputs a comparison-result signal C442 to the comparison circuit 443.

Reduction of Data 1 to Data 16 is performed by the above-structured comparison circuits 441 to 455 as follows. It is assumed that the logical levels of Data 1 to Data 16 are either 0 or 1. Each comparison circuit compares the logical levels of two input signals and determines the logical level of a comparison result signal as 1 if the logical levels of the two input signals are identical, or the logical level of the comparison result signal as 0 if the logical levels of the two input signals are not identical, and outputs the comparison-result signal to the posterior comparison circuit.

Since the logical levels of Data 1 and Data 2 are identical, the comparison circuit 441 outputs the comparison result signal C441 indicative of the logical level 1 to the comparison circuit 442.

Then, the comparison circuit 442 compares the logical levels of Data 2 and Data 3, and determines the logical level of a comparison result signal as 1. Further, the comparison circuit 442 compares the logical level of the comparison result signal and the logical level of the comparison-result signal C441 that is 1, and outputs a comparison-result signal C442 indicative of logical level 1 to the comparison circuit 443.

Similarly, the comparison circuit 443 outputs a comparison-result signal C443 indicative of logical level 1 to the comparison circuit 444. Then, the comparison circuit 444 outputs a comparison-result signal C444 indicative of logical level 1 to the comparison circuit C445. Finally, the comparison circuit 447 outputs a comparison-result signal C447 indicative of logical level 1 to the comparison circuit 456.

On the other hand, the comparison circuit 455 positioned rightmost outputs a comparison-result signal C455 indicative of logical level 1 to the comparison circuit 454 since the logical levels of Data 15 and Data 16 are identical. Similarly, the comparison circuit 454 outputs a comparison-result signal C454 indicative of logical level 1 to the comparison circuit 453. Then, the comparison circuit 453 outputs a comparison-result signal C453 indicative of logical level 1 to the comparison circuit 452. Finally, the comparison circuit 448 outputs a comparison-result signal indicative of logical level 1 to the comparison circuit 456.

Then, the comparison circuit 456 outputs a comparison-result signal C456 indicative of logical level 1 to the I/O buffer 428 since the logical levels of the comparison-result signal C447 and C448 are identical. Then, the I/O buffer 428 stores the input comparison-result signal C456 and outputs the input comparison-result signal C456 to the pad P408.

Thus, the circuit unit 400 outputs a reduction-result signal of logical level 1, i.e., indicating that Data 1 to Data 16 are identical to the pad 408.

If any one of the logical levels of Data 1 to Data 16 is different, any one of the comparison circuits 441 to 448 outputs a comparison-result signal indicative of logical level 0. Then, the circuit unit 400 outputs a reduction-result signal indicative of logical level 0, i.e., indicating that Data 1 to Data 16 are not identical, to the pad P408.

Thus, the circuit unit 400 in the I/O reduction-test mode outputs, to the pad P408, a signal indicative of logical level 1 if all input data are identical or a signal indicative of logical level 0 if all input data are not identical.

Although the circuit unit 400 compares two input data through the comparison circuits, the circuit unit 400 may compare three or more data. For example, the circuit unit 400 compares Data 1 to Data 16 with an expectation value of 16 bits preliminarily written into a register.

As explained above, the I/O reduction-test mode in which only the pad P408 is probed can be used for wafer-probing. Therefore, only the probe region 5 of the pad P408 is probed upon wafer-probing, and the wire-bonding regions of the pads P401 to 416 are not scratched.

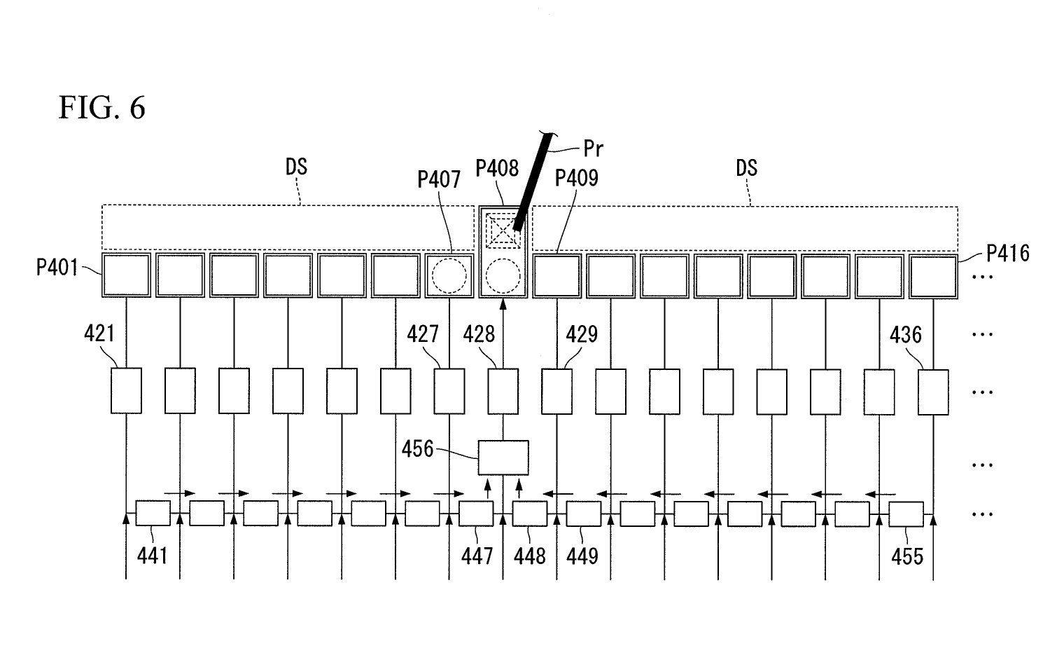

FIG. 6 illustrates the case where the second pads P401 to P407 and P409 to P416 that are not probed are made smaller than the first pad P408 to be probed. FIG. 6 is the same as FIG. 5 except that the sizes of the pads P401 to P407 and P409 to P416 are changed.

If the first pad P408 is disposed with the longer sides thereof being along the direction perpendicular to the alignment direction of the pads P401 to P416, dead space DS occurs as shown in FIG. 6.

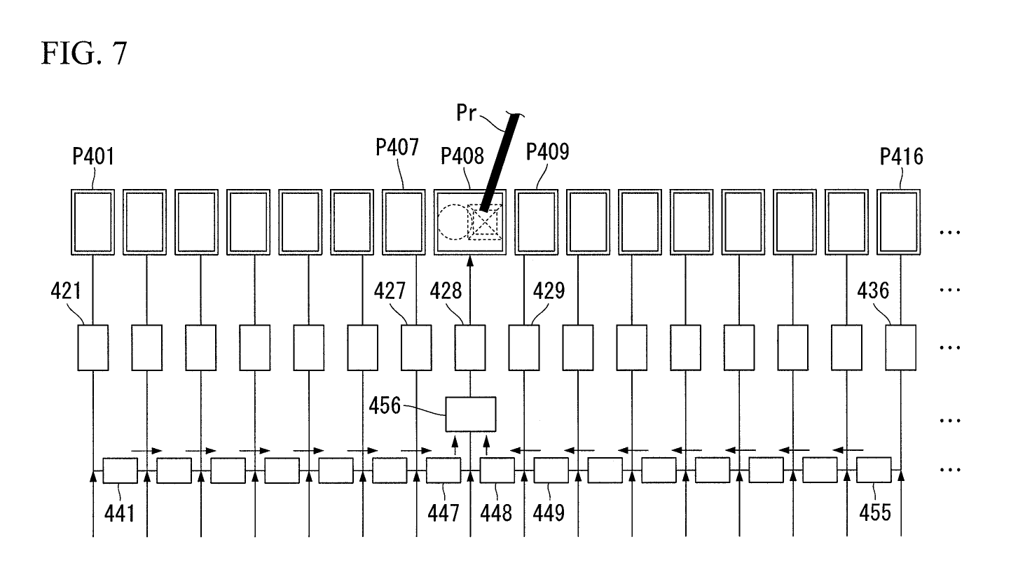

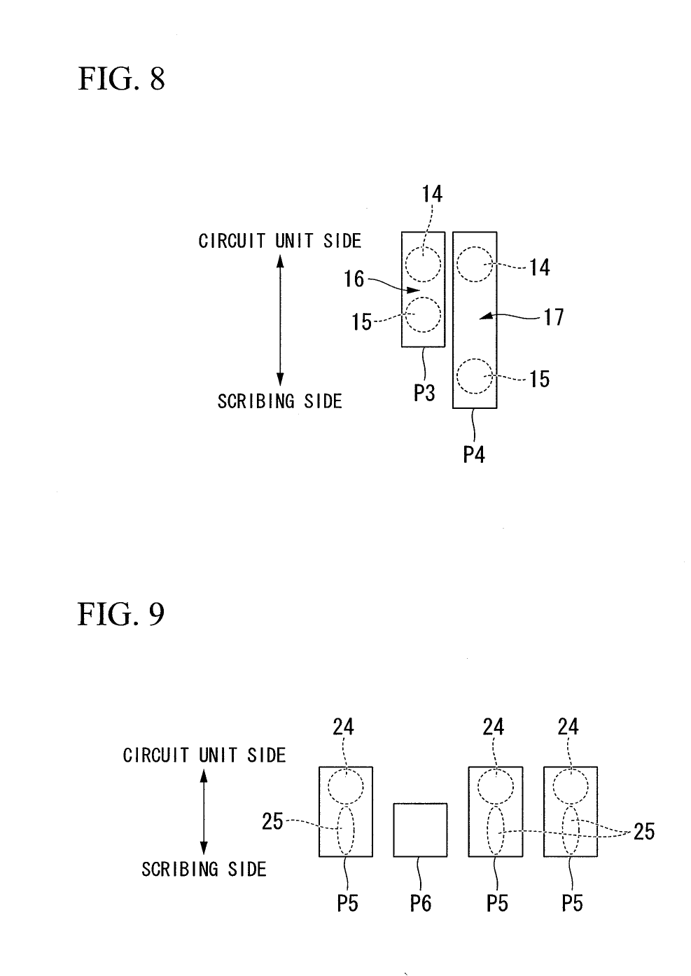

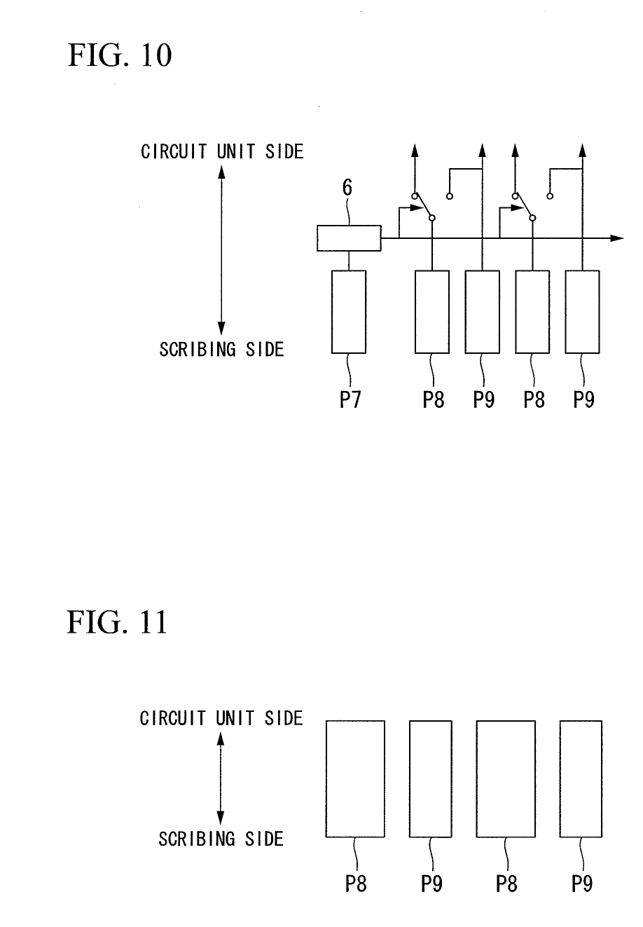

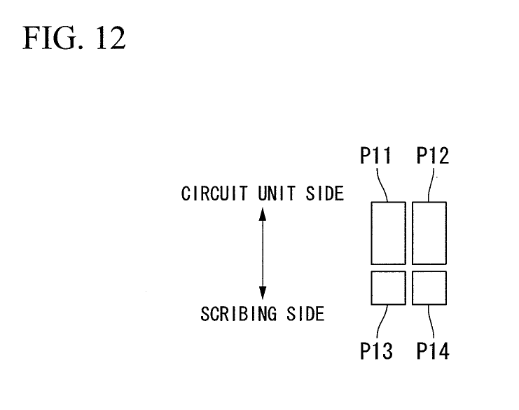

On the other hand, if the first pad P408 is disposed with the longer sides thereof being along the direction in parallel with the alignment direction of the pads P401 to P416 as shown in FIG. 7, dead space DS as shown in FIG. 6 does not occur, and therefore the pads P401 to P416 can be aligned in a line.

Although the case where the first pad of the first embodiment is applied to the I/O pads has been explained, the present invention is not limited thereto, and the first pad is applicable to power pads.

The present invention is applicable to semiconductor devices including a circuit unit and multiple pads.

It is apparent that the present invention is not limited to the above embodiments, but may be modified and changed without departing from the scope and spirit of the invention.

What is claimed is:

1. A semiconductor device, comprising
a plurality of first pads and second pads aligned along a first direction, wherein
lengths of the first pads in parallel with the first direction are longer than those of the second pads in parallel with the first direction.

2. The semiconductor device according to claim 1, wherein lengths of the first pads in a second direction perpendicular to the first direction are substantially identical to those of the second pads in the second direction.

3. The semiconductor device according to claim 1, wherein the first pads and the second pads are rectangular, if planarly viewed.

4. The semiconductor device according to claim 1, wherein the first pads are larger than the second pads.

5. The semiconductor device according to claim 1, wherein the first pads and the second pads are aligned in a line.

6. The semiconductor device according to claim 1, wherein
each of the first pads comprises a probe region and a wire-bonding region, and
each of the second pads comprises the wire-bonding region and is free from the probe region.

7. The semiconductor device according to claim 6, wherein the probe region and the wire-bonding region included in each of the first pads are aligned in the first direction.

8. The semiconductor device according to claim 1, wherein data input to the second pads is output through the first pads in a probe test.

9. The semiconductor device according to claim 1, wherein the probe region and the wire-bonding region overlap each other in each of the first pads.

10. A semiconductor device, comprising:
a first pad and a second pad, the first pad being larger than the second pad;
a first buffer that outputs first data to the first pad and a second buffer that outputs second data to the second pad; and
a comparison circuit that compares the first data with the second data and outputs a result of the comparison to the first pad.

11. The semiconductor device according to claim 10, wherein
the first pad and the second pad aligned along a first direction, and
length of the first pad in parallel with the first direction is longer than that of the second pad in parallel with the first direction.

12. The semiconductor device according to claim 11, wherein length of the first pad in a second direction perpendicular to the first direction is substantially identical to that of the second pad in the second direction.

13. The semiconductor device according to claim 10, wherein the first pad and the second pad are rectangular, if planarly viewed.

14. The semiconductor device according to claim 10, wherein the first pad and the second pad are aligned in a line.

15. The semiconductor device according to claim 10, wherein
the first pad comprises a probe region and a wire-bonding region, and
the second pad comprises the wire-bonding region and is free from the probe region.
